(19) United States
(12) Patent Application Publication
(10) Pub. No.: US 2026/0304596 A1
(43) Pub. Date: Oct. 1, 2026

(54) CHASSIS AS LOW-SPEED TRANSMISSION LINE IN A COMPUTING DEVICE

(71) Applicant: Intel Corporation, Santa Clara, CA (US)

(72) Inventors: Nithesha Ananda, Surathkal (IN); Sagar Gupta, Ghaziabad (IN); Jay Vishnu Gupta, Bangalore (IN); Navneet Kumar Singh, Bangalore (IN); Phani Alaparthi, Bangalore (IN); Prasanna Pichumani, Bangalore (IN); Prakash Kurma Raju, Bangalore (IN)

(73) Assignee: Intel Corporation, Santa Clara, CA (US)

(21) Appl. No.: 19/094,364

(22) Filed: Mar. 28, 2025

(51) Int. Cl. H05K 1/02

(52) U.S. Cl. CPC H05K 1/0213; H05K 1/0201

(57) ABSTRACT

A heat and signal carrying member provides routing for low-speed signals in a computing device. A computing device includes a printed circuit board, a member, and a peripheral component. The member includes a first layer including a thermally conductive material, a second layer including a dielectric material, and a third layer including a transmission line. The peripheral component is conductively coupled to the printed circuit board by the first transmission line of the member. A first connector connects the peripheral component to the transmission line, and a second connector connects the printed circuit board to the transmission line. The thermally conductive material may include graphite.

### BACKGROUND

As technology evolves, computing devices offer increasingly more features and functionalities. New features and functionalities are often coupled with additional wires or flexible printed circuits (FPCs) for carrying signals to enable new devices. Additionally, as the size of devices continues to shrink, routing the numerous wires to support the myriad of integrated devices adds system complexity and consumes space on the printed circuit boards (PCBs) and flexible PCBs (FCBs) and within the device chassis. Consequently, designing ever smaller systems with maximized features and functionalities is challenging.

### BRIEF DESCRIPTION OF THE DRAWINGS

FIG. 1A is a front and side perspective view of an example computing device in an open position with a first example heat and signal carrying member according to one or more embodiments.

FIG. 1B is a front and side perspective view of the example computing device of FIG. 1A in an open position with a second example heat and signal carrying member according to one or more embodiments.

FIG. 2 is a cross-sectional side view of an example layered structure of a chassis of a computing device according to one or more embodiments.

FIG. 3 is diagram of an example heat and signal carrying member according to one or more embodiments.

FIG. 4A is a cutaway of the cross-sectional side view of the layered structure of FIG. 2 including an example connector that may be used in one or more embodiments.

FIG. 4B is a side view of an example multi-pin connector that may be used in one or more embodiments.

FIG. 5 is an example multi-terminal connector that may be used in one or more embodiments.

FIGS. 6A-6E illustrate an example process for creating a heat and signal carrying member with transmission lines according to one or more embodiments.

FIG. 7 is an example method of a process for creating a heat and signal carrying member with transmission lines according to one or more embodiments.

FIG. 8 is a block diagram of an example computing system in which technologies described herein may be implemented.

FIG. 9 is a block diagram of an example processor to execute computer-executable instructions as part of implementing technologies described herein.

### DETAILED DESCRIPTION

The present disclosure provides various possible embodiments, or examples, of systems, methods, and apparatuses for leveraging a heat carrying member in a chassis of a computing device to route low-speed signals of various components in the chassis. One or more heat carrying members (e.g., sheets made of graphite or other suitable thermally conductive material) are routinely incorporated in computing devices to spread heat produced by heat sources in the device from one area to another area and thus enable more effective heat dissipation from the device. In one or more embodiments, suitable dielectric and electrically conductive layers may be added to a heat carrying member for a computing device and configured with transmission lines (or traces) in the electrically conductive layer to route low-speed signals of electronic components in the device. Techniques for forming the desired transmission lines include, for example, printing and/or etching. Suitable connectors can be used to conductively couple first ends of transmission lines formed on the heat carrying member to respective peripheral components that receive and/or produce low-speed signals and to conductively couple second ends of the transmission lines to a motherboard or other printed circuit board.

To better understand the techniques of the various embodiments in this disclosure, the following contextual information related to the challenges of designing computing systems with ever-increasing features and capacities (e.g., memory, battery, peripheral devices, etc.). Generally, in computing devices such as laptops, tablets, and other similar devices, wires and/or flexible printed circuits (FPCs) are used to route low-speed signals between a processor (e.g., central processing unit (CPU), graphical processing unit (GPU), microprocessor, embedded controller, etc.) on a printed circuit board (PCB) and peripheral components in the device. In typical laptop designs that include a first chassis (e.g., a lid panel) and a second chassis (e.g., a base panel), for example, multiple peripheral components are placed in the lid panel and in the base panel to perform a variety of functions and enable features of the computing device. Generally, a lid panel is intended to mean a member or portion (e.g., lid portion) of a computing device in which a screen for displaying electronic information or content is disposed. A base panel is intended to mean a member or portion (e.g., base portion) of a computing device in which computing hardware (e.g., processor, CPU, motherboard, SOC, etc.) is disposed. A screen may or may not be disposed in a base panel.

As used in this specification, “peripheral component” is intended to include any device that is conductively coupled to a processor (e.g., central processing unit (CPU), graphical processing unit (GPU), etc.), microprocessor, embedded controller, or other electronic component on a printed circuit board (PCB) that can communicate with the peripheral component. In this specification, references to a “remote peripheral component” are intended to mean a given peripheral component that is implemented in a panel, member, or other portion of a computing device (e.g., laptop, dual display device, foldable device, etc.) that is coupled to another panel, member, or other portion that contains a processor (or other electronic component) on a PCB to which the given peripheral component is conductively coupled. References to a “local peripheral component” are intended to mean a given peripheral component that is implemented in a panel, member, or other portion of a computing device that contains a processor (or other electronic component) on a PCB to which the given peripheral component is conductively coupled.

A peripheral component may be capable of sending signals to a processor (output), receiving signals from a processor (input), or both. Signals include electrical signals, such as power and/or information-carrying signals (e.g., one or more bits, one or more bytes, etc.). Signals that are communicated between a peripheral component and a processor may depend on the particular communication protocol that is used, and may include one or more of data (e.g., user and/or system information), control signals (e.g., device management information, status information, initialization information, configuration information, etc.), clock signals, power signals, and/or interrupt signals (e.g., alert CPU of interrupt events, send interrupt-related information, etc.), audio signals, video signals, etc.

Low-speed signals are messages in the form of electrical signals that operate at relatively low frequencies and data rates and that do not require controlled impedance. Such signals are commonly used for communication between peripheral components and components on a motherboard in the computing system. For example, low-speed signals can include, but are not necessarily limited to speaker amplifier signals, specific absorption rate (SAR) signals, sensor signals, Hall sensor signals, privacy switch signals, mute signals, microphone signals, embedded controller signals for handling low-level hardware tasks (e.g., scanning inputs of keyboard and trackpad, thermal monitoring of fan control and sensors, communication to CPU, etc.), trackpad signals, battery status signals, keyboard signals, and web camera signals. Buses or transmission lines over which low-speed signals travel may use communication protocols such as Inter-Integrated Circuit (I2C), Serial Peripheral Interface (SPI), Universal Asynchronous Receiver-Transmitter (UART), General Purpose Input/Output (GPIO) digital signal pins, System Management Bus (SMBus), Low Pin Count (LPC) Bus, and/or some versions of Universal Serial Bus (USB) (e.g., USB 1.1), for example.

As the number of features and peripheral components offered in computing devices continues to grow, more and more space in the chassis is consumed by wires and/or FPC routing for those features and peripheral components. In addition, many computing devices (e.g., mobile devices such as mobile phones, laptops, tablets, etc.) continue to scale downward. As the size and thickness of such devices are reduced, this further limits the space in a chassis of those devices. Consequently, the space available for increasing the capacity of other components may shrink. For example, reducing space within the chassis to incorporate new features and peripheral components and/or to design a thinner and smaller computing device, can result in undesirable trade-offs of forgoing greater battery capacity and/or additional memory capacity and/or additional compute capacity.

In addition to consuming space within a chassis, the significant number of wires and FPCs used for routing low-speed signals in computing systems can present further challenges. In particular, system complexity may increase as the number of wires and FPCs for signal routing increases. For remote peripheral components, the wires extend from one chassis (e.g., lid panel) into another chassis (e.g., base panel). The wires consume valuable space within the housing and increase complexity due to the large number of wires, some of which are located within the base panel where the motherboard is located and some of which traverse a hinge to pass from the lid panel to the base panel. Additionally, wire and FPC signal routing increases the overall bill of material costs. Thus, new approaches for routing low-speed signals are needed to preserve space in the chassis and reduce the complexity of systems.

Embodiments disclosed herein can resolve the aforementioned issues (and more) associated with wire and FPC routing in compact computing systems. For example, a heat and signal carrying member in a chassis of computing system may be utilized as a transmission line for low-speed signals that do not require controlled impedance (e.g., audio signals, sensor signals, SAR control signals, etc.). In some scenarios, the heat and signal carrying member may be a graphite sheet that is configured with electrically conductive lines or traces by a suitable technique such as etching or printing, for example. Opposite ends of each transmission line on the graphite sheet may be conductively coupled to a peripheral device and a motherboard (or other PCB or component) by any suitable conductive connectors such as pogo pins or spring terminals, for example. In some embodiments, the heat and signal carrying member may be contained in a single chassis with electronic components. In other embodiments, the heat and signal carrying member may extend between multiple chassis and possibly across a hinge.

Several advantages can be realized by utilizing a heat and signal carrying member having transmission lines to route low-speed signals in a chassis. The typical wire and FPC routing of the low-speed signals can be eliminated from the chassis and instead, can be routed over the heat and signal carrying member. Thus, the additional space created by using a heat and signal carrying member for low-speed signals can provide room for greater battery capacity or other components and/or features. In addition, the system complexity can be improved. Furthermore, the cost of the system can be reduced due to the elimination of the wire and FPC routing of the low-speed signals. In embodiments using a heat and signal carrying member extended between two chassis, such as a lid panel and a base panel of a laptop, the number of wires in a lid panel and across a hinge can be reduced, while dispersing heat away from the electronic components in the base more effectively. Also, because the transmission lines of the heat and signal carrying member route low-speed signals that do not require impedance control, the risks of electromagnetic interference (EMI), electromagnetic compatibility (EMC), and radio frequency interference (RFI) are minimal or nonexistent.

Reference is now made to the drawings, which are not necessarily drawn to scale, and where similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

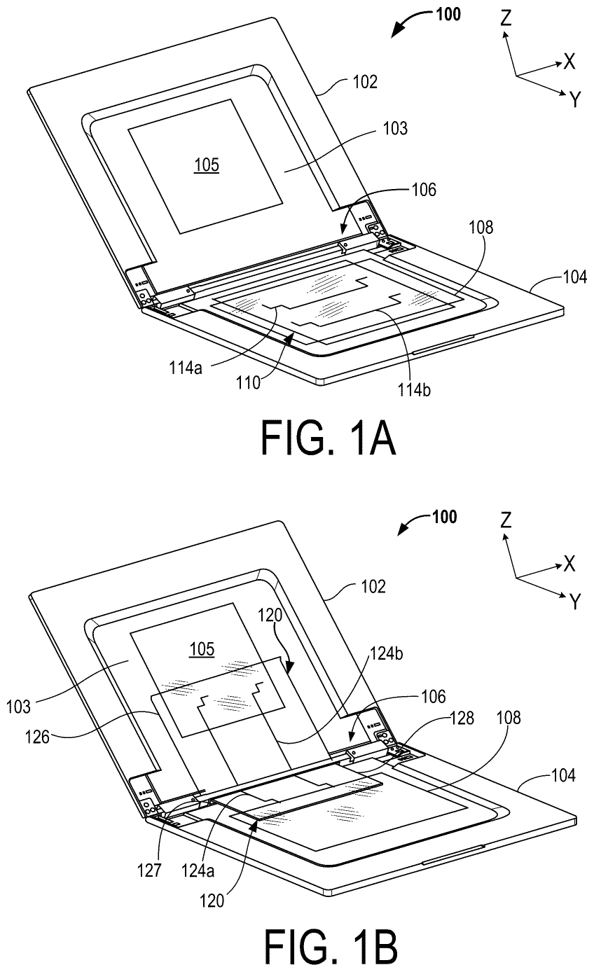

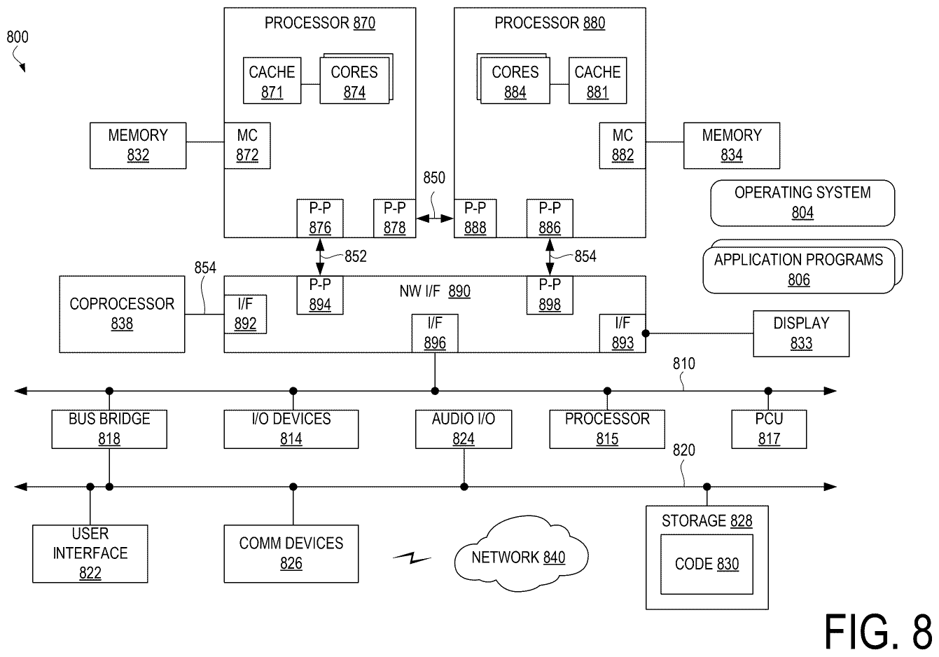

FIG. 1A is a front and side perspective view of an example computing device 100 in an open position with a heat and signal carrying member 110 according to one or more embodiments. In this example, computing device 100 includes a first chassis 102 (e.g., a lid panel) and a second chassis 104 (e.g., a base panel). In at least one embodiment, first chassis 102 may include a display (shown in FIG. 8) located in an area 103, which is visible when the computing device 100 is in the open position. The first chassis 102 may also contain remote peripheral components 105. Examples of such components can include, but are not necessarily limited to, a camera (e.g., Mobile Industry Processor Interface (MIPI) camera), microphones, one or more sensors, a light emitting diode (LED), and/or an electric shutter. In addition, a human interface device (HID), such as a touch screen with a touch controller, may also be disposed in the first chassis 102. A HID device may include any device (typically hardware) that is configured to receive human input that interacts with a computing device and may provide output. Examples include, but are not limited to, a touch screen, keyboards and pointing devices, manual panel controls, etc. These examples are not exhaustive and it should be appreciated that any other peripheral components, sensing devices, human interface devices, or any combination thereof may be added to a lid panel of a laptop to support desired features and functionalities. The peripheral components and HID devices in the first chassis 102 connect to a processor (e.g., CPU) in the second chassis 104, and wires are required to traverse a hinge assembly 106 that connects the first chassis 102 to the second chassis 104.

The second chassis 104 may house one or more electronic components 108. For ease of description, the electronic components 108 are transparently depicted in FIG. 1A in order to allow for visibility of member 110. Electronic components 108 can include compute (e.g., central processing unit (CPU), graphics processing unit (GPU), microprocessors, embedded controllers, chipset, etc., which may be attached to a printed circuit board or motherboard) and/or other high power components (e.g., battery, etc.) and/or local peripheral components, for example. Examples of the local peripheral components may include, but are not necessarily limited to, speakers, specific absorption rate (SAR) sensors, Hall sensors, other sensors, privacy switches, microphones, embedded controllers for handling low-level hardware tasks (e.g., scanning inputs of keyboard and trackpad, thermal monitoring of fan control and sensors, communication to CPU, etc.), trackpads, battery status indicator, and keyboards. Although examples of remote and local peripheral components have been provided for illustration purposes herein, such components may be implemented in the first chassis 102 or the second chassis based on the particular design of the computing device, and are not limited to implementation in a particular chassis.

A hinge assembly 106 can rotatably couple first chassis 102 to second chassis 104. First chassis 102 may be capable of rotation relative to second chassis 104, and second chassis 104 may be capable of rotation relative to first chassis 102. In at least one embodiment, computing device 100 is convertible, in which first chassis 102 is rotatable between zero degrees (0°) and three hundred sixty degrees (360°) relative to second chassis 104, and/or second chassis 104 is rotatable between zero degrees (0°) and approximately three hundred sixty degrees (360°) relative to first chassis 102. It should be noted that embodiments herein may be implemented in numerous other types of devices. For example, embodiments may be implemented in computing devices that are not necessarily convertible (e.g., range of rotation is between zero degrees (0°) and approximately one hundred eighty degrees (180°)), or that have a single chassis (e.g., tablet, etc.), or that have more than two chassis.

Generally, the heat and signal carrying member 110 is sized for placement within the second chassis 104 such that member 110 extends at least partially across one or more of the electronic components 108. In one example, as shown in FIG. 1A, member 110 is positioned in the second chassis 104 below one or more of the electronic components 108. In other examples, member 110 may be positioned in the second chassis 104 above one or more of the electronic components 108. In yet other examples, member 110 may be positioned in the second chassis 104 between two or more of the electronic components 108.

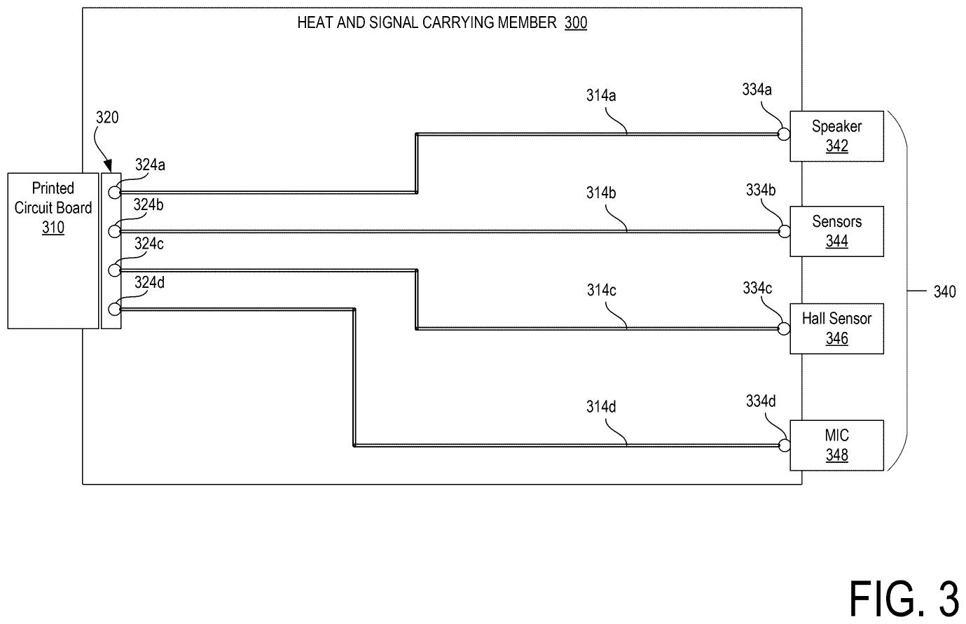

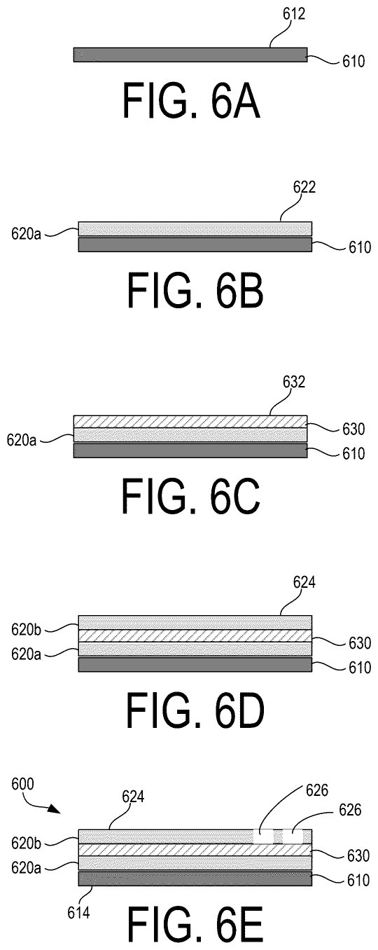

In one or more embodiments, the heat and signal carrying member 110 may be formed from a base layer of material that has a high thermal conductivity, such as graphite, for example. The thermal conductivity of graphite may be in the range of 1000 to 1500 Watts per meter per Kelvin (W/mK). In some embodiments, other thermally conductive materials may be included in a base layer. For example, a thermal interface material (TIM) having a lower thermal conductivity (e.g., 8 to 25 W/mK) could be included. The heat and signal carrying member 110 also includes an interconnect structure disposed on the base layer (as shown in FIG. 3 and FIGS. 6A-6E). The interconnect structure includes one or more transmission lines formed of an electrically conductive material (e.g., copper or other metal) for carrying low-speed signals. One or more of the transmission lines may be configured to transmit low-speed signals that do not require controlled impedance.

In this example, the heat and signal carrying member 110 includes two transmission lines 114a and 114b. One end of each transmission line 114a and 114b can be conductively coupled to a respective local peripheral component, which may be part of the electronic components 108. An opposite end of each transmission line 114a and 114b can be conductively coupled to a printed circuit board (PCB), which may be part of the electronic components 108, in order to communicate with a processor or other electronic component attached to the PCB. The printed circuit board (PCB) could be a rigid PCB, a flexible PCB (FPCB), or a rigid-flex PCB, depending on the device. The PCB could be a motherboard of the device or an additional PCB (e.g., daughterboards) in the device that may be conductively coupled to the motherboard.

The coupling of the transmission lines 114a and 114b to the peripheral components and the printed circuit board may be achieved by any suitable electrically conductive connector. For example, pogo pins and/or spring terminals may be used in some implementations.

Although transmission lines 114a and 114b are illustrated as generally extending along the width of the second chassis 104, it should be apparent that one or both of the transmission lines 114a and 114b and/or other transmission lines (not shown), could be configured to extend in any suitable direction across the member 110 in order to couple a peripheral component to an electronic device directly or via a printed circuit board (PCB).

In at least one embodiment, the heat and signal carrying member 110 can be securely attached to the second chassis 104. Any suitable attachment means may be used to securely attach the heat and signal carrying member 110 to second chassis 104 (e.g., fasteners, screws, nuts, bolts, adhesive, etc.). Such attachment means may attach the heat and signal carrying member directly to the chassis and/or to one or more electronic components or elements within two chassis.

FIG. 1B is a front and side perspective view of the example computing device 100 in an open position with a second example heat and signal carrying member 120 according to one or more embodiments. The heat and signal carrying member 120 extends from within first chassis 102, through hinge assembly 106, into second chassis 104. The heat and signal carrying member 120 includes a first chassis portion 126 disposed in first chassis 102, a second chassis portion 128 disposed in second chassis 104, and a middle portion 127 extending through hinge assembly 106 and disposed between the first chassis and the second chassis. In one example, first chassis portion 126 of the heat and signal carrying member 120 may be disposed behind a display (shown in FIG. 8) contained in first chassis 102. Similarly, second chassis portion 128 of the heat and signal carrying member 120 may be disposed behind a keyboard, a second display, or any other outwardly facing user interface or other components contained in second chassis 104.

The heat and signal carrying member 120 may be configured to facilitate shared cooling between first chassis 102 and second chassis 104. In this example, most heat associated with computing device 100 is generated by electronic components 108 in second chassis 104, such as compute and other high-power components, for example. Second chassis portion 128 of the heat and signal carrying member 120 can be configured to receive heat from electronic components 108 and to transfer at least some of the heat received from electronic components 108 to first chassis portion 126 of the heat and signal carrying member 120 by the heat flowing from the second chassis portion 128, through middle portion 127, to first chassis portion 126. First chassis 102 may provide additional surface area through which thermal energy that spreads into first chassis portion 126 can escape. Thus, use of the heat and signal carrying member 120 can facilitate heat dissipation via surface areas of first chassis 102, in addition to heat dissipation already occurring in second chassis 104.

In at least one embodiment, the heat and signal carrying member 120 can be securely attached to the two chassis. For example, first chassis portion 126 of the heat and signal carrying member 120 may be securely attached within first chassis 102, and second chassis portion 128 of the heat and signal carrying member 120 may be securely attached within second chassis 104. Any suitable attachment means may be used to securely attach the heat and signal carrying member 120 to first chassis 102 and second chassis 104 (e.g., fasteners, screws, nuts, bolts, adhesive, etc.). Such attachment means may attach the heat and signal carrying member 120 directly to the two chassis and/or to one or more components or elements within two chassis. Middle portion 127 of the heat and signal carrying member 120, however, may be permitted to float and may not be securely attached to any particular structure in the hinge area between first chassis 102 and second chassis 104.

Generally, the second chassis portion 128 of member 120 is sized for placement within the second chassis 104 such that the second chassis portion 128 extends at least partially across one or more of the electronic components 108. In one example, as shown in FIG. 1B, the second chassis portion 128 of member 120 is positioned in the second chassis 104 below one or more of the electronic components 108. In other examples, the second chassis portion 128 of member 120 may be positioned in the second chassis 104 above one or more of the electronic components 108. In yet other examples, the second chassis portion 128 of member 120 may be positioned in the second chassis 104 between two or more of the electronic components 108.

Generally, the first chassis portion 126 of member 120 is sized for placement within the first chassis 102 such that the first chassis portion 126 extends at least partially across one or more of the electronic components 108. In one example, as shown in FIG. 1B, the first chassis portion 126 of member 120 is positioned in the first chassis 102 below one or more of the peripheral components 105. In other examples, the first chassis portion 126 of member 120 may be positioned in the first chassis 102 above one or more of the peripheral components 105. In yet other examples, the first chassis portion 126 of member 120 may be positioned in the first chassis 102 between two or more of the peripheral components.

In this example, the heat and signal carrying member 120 includes two transmission lines 124a and 124b. The ends of transmission lines 124a and 124b disposed in the first chassis portion 126 of member 120 are conductively coupled to respective remote peripheral components 105. The opposite ends of transmission lines 124a and 124b disposed in the second chassis portion 128 of member 120 may be conductively coupled to a printed circuit board (PCB), which may be part of the electronic components 108, in order to communicate with a processor or other electronic component attached to the PCB.

The coupling of the transmission lines 124a and 124b to peripheral components and the printed circuit board may be achieved by any suitable electrically conductive connector. For example, pogo pins and/or spring terminals may be used in some implementations.

Although transmission lines 124a and 124b are illustrated as generally extending along the length of the member 120, it should be apparent that one or both transmission lines 124a and 124b and/or other transmission lines (not shown), could be configured to extend in any suitable direction across the member 120 in order to couple a peripheral component to an electronic device directly or via a printed circuit board (PCB).

In some scenarios, a heat and signal carrying member that extends between chassis, such as the heat and signal carrying member 120, may only include transmission lines that conductively couple (e.g., directly or via a PCB) remote peripheral components 105 in the first chassis 102 to an electronic components 108 in the second chassis 104 (e.g., either directly or via a printed circuit board). In other embodiments, additional transmission lines formed in only the second chassis portion 128 of the heat and signal carrying member 120 may be used to conductively couple (e.g., directly or via a PCB) local peripheral components in the second chassis 104 to electronic components 108 in the second chassis 104. In yet another embodiment, another heat and signal carrying member similar to the heat and signal carrying member 110 may be disposed in the second chassis 104 in addition to the heat and signal carrying member 120. In this scenario, the heat and signal carrying member 120 could conductively couple remote peripheral components 105 to electronic components 108 in the second chassis 104, and the additional heat and signal carrying member in the second chassis 104 could conductively couple local peripheral components in the second chassis 104 to electronic components 108 in the second chassis 104.

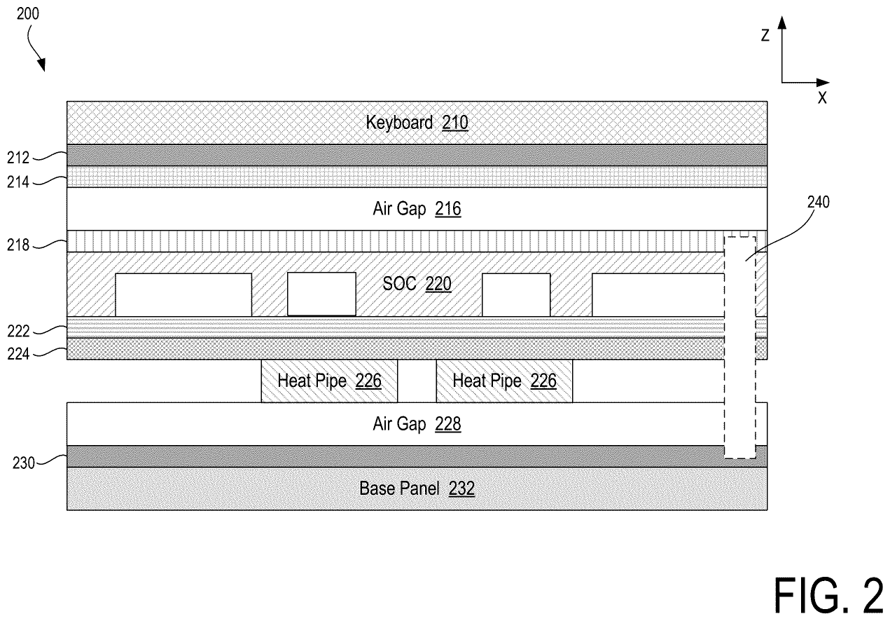

FIG. 2 is a cross-sectional side view of an example layered structure 200 of a chassis of a computing device according to one or more embodiments. The layered structure 200 shows one possible layered arrangement of electronic components, mechanical components, a printed circuit board, and other materials in a chassis (e.g., second chassis 104) of a computing device (e.g., computing device 100) that may be configured with a heat and signal carrying member 230 (e.g., similar to heat and signal carrying member 110 or 120) according to one or more embodiments.

As shown in FIG. 2, the layered structure 200 includes a base panel 232 and a heat and signal carrying member 230 that is disposed on top of the base panel 232. An air gap 228 (or heat sink) may be provided between the heat and signal carrying member 230 and one or more heat pipes 226 to help manage the temperature in the chassis. A cold plate 224 may be disposed on top of the heat pipes 226. The cold plate 224 may be, for example a thermally conductive material that absorbs heat from electronic components in the chassis, such as an SOC (system-on-a-chip) 220 above the cold plate.

The SOC 220 may be disposed above the cold plate 224 and another optional layer 222, which could be another cold plate or a pedestal. The SOC 220 may include one or more processors and other integrated circuit components (e.g., memory, storage controllers, input/output interfaces, network interfaces, wireless interfaces, power management controllers, etc.), that are attached to a printed circuit board (PCB) 218, which is above the SOC 220 in the layered structure 200. The printed circuit board 218 could be a rigid PCB, a flexible PCB, or a rigid-flex PCB, depending on the device. The PCB could be a motherboard of the device or an additional PCB (e.g., daughterboard) in the device that may be conductively coupled to the motherboard. In some embodiments, one or more additional integrated circuit components or other components, such as a battery or antenna, can be attached to the printed circuit board. In some embodiments, one or more separate printed circuit boards may be conductively coupled to the printed circuit board 218 within the same computing device.

A mounting plate 214 may be above the printed circuit board 218 and spaced from the printed circuit board 218 to define an air gap 216 therebetween. In some scenarios, a second heat carrying member 212 may be provided above the mounting plate 214 and below a keyboard 210 and/or one or more other input components (e.g., display, track pad, etc.). The second heat carrying member 212 may disperse heat produced from the keyboard 210 and/or one or more other input devices above the second heat carrying member 212.

In some embodiments, the base panel 232 forms part of a housing of a computing device that encloses the layers 212-230 between the keyboard 210 and the base panel 232.

The heat and signal carrying member 230 includes one or more transmission lines for transmitting low-speed signals from a peripheral component to the printed circuit board 218. Such signals may then be routed to appropriate electronic components indicated, for example, by the SOC 220. In other possible implementations, the electronic components that receive low-speed signals from, or send low-speed signals to, a peripheral device over transmission lines in the heat and signal carrying member 230 may not necessarily be implemented as a system-on-a-chip, but may be discrete components implemented on the same or different circuit boards in the computing device.

A transmission line (e.g., similar to transmission line 114a or 114b of FIG. 1A, or transmission line 124a or 124b of FIG. 1B) in the heat and signal carrying member 230 may be conductively coupled to the printed circuit board 218 using any suitable electrically conductive connector. The connector may be disposed in a cavity 240 that extends from an exposed end of the transmission line (or a conductive contact at an exposed end of the transmission line) in the member 230 to a conductive contact on the printed circuit board 218. In one example, a spring-loaded connector, such as a pogo pin, may be disposed in the cavity 240 to form a conductive coupling with both the transmission line in the heat and signal carrying member 230 and the printed circuit board 218, such that electrical signals can be passed between the transmission line and the printed circuit board and appropriate electronic components on the printed circuit board 218. In other examples, a spring terminal or any other suitable electrical connecting mechanism may be disposed in the cavity 240 to form the conductive coupling. Generally, as used herein, a “conductive contact” is intended to mean any conductive area (e.g., contact, pad, bump, trace, line, or wire) to which a connector may be connected to form an electrically conductive path, where the connection may be made using any suitable technique such as, for example, soldering, pressing by a spring mechanism, press-fitting, clamping, docking a multi-pin or multi-terminal connector, etc.

The heat and signal carrying member 230 may extend laterally (or horizontally along the X-axis) beyond the printed circuit board 218 to align with one or more peripheral components in the chassis. A similar connector (e.g., spring-loaded connector, spring terminal, etc.) may be used between the transmission line in member 230 and a peripheral component to form a conductive coupling such that electrical signals can be passed between the transmission line and the peripheral component to which the transmission line is connected by the conductive coupling. It should be noted that although multiple transmission lines may be formed in the heat and signal carrying member 230, with multiple connectors conductively coupling first ends of the transmission lines to respective peripheral components, and multiple other connectors conductively coupling second ends of the transmission lines to respective electronic components via the printed circuit board.

In one or more embodiments, the second heat carrying member 212 may be formed with transmission lines (e.g., similar to transmission line 114a or 114b of FIG. 1A, or transmission line 124a or 124b of FIG. 1B) in addition to or instead of the transmission lines formed on the heat and signal carrying member 230. Thus, in one example, some or all of the transmission lines on heat and signal carrying member 230 may be formed on the second heat carrying member 212. In another example, the second heat carrying member 212 will include transmission lines for additional peripheral components that are not supported by transmission lines in the heat and signal carrying member 230.

FIG. 3 is diagram of an example heat and signal carrying member 300 with example transmission lines conductively coupled to peripheral components and a printed circuit board. according to one or more embodiments. The heat and signal carrying member 300 is one possible example of heat and signal carrying members described herein (e.g., heat and signal carrying members 110, 120, 230, second heat carrying member 212). The heat and signal carrying member 300 may include a base layer of a material having a high thermal conductivity (e.g., graphite or other suitable material). In addition, an interconnect structure may be disposed above the base layer (as shown in FIGS. 6A-6E). The interconnect layer includes transmission lines 314a, 314b, 314c, and 314d. In at least some examples, a dielectric layer comprising a dielectric material (e.g., a laminate) may be disposed in between the transmission lines and on top of the transmission lines 314a-314d, with selected portions of the dielectric layer etched away to expose opposite ends of each transmission line.

Exposed first ends of transmission lines 314a, 314b, 314c, and 314d may be conductively coupled to respective peripheral components 340. The conductive coupling may be achieved with any suitable connector that allows electrical signals to pass between the transmission line and the peripheral component to which the transmission line is conductively coupled. Examples of suitable connectors include, but are not limited to spring-loaded connectors (or “pogo pins”), multi-pin connector, spring terminal, or multi-terminal connector). For example, an exposed first end of transmission line 314a may be conductively coupled to a speaker 342 by a connector 334a. An exposed first end of transmission line 314b may be conductively coupled to a sensor 344 (e.g., proximity sensor) by a connector 334b. An exposed first end of transmission line 314c may be conductively coupled to a Hall sensor 346 by a connector 334c. An exposed first end of transmission line 314d may be conductively coupled to a microphone 348 by a connector 334d.

Exposed second ends of transmission lines 314a, 314b, 314c, and 314d may be conductively coupled to a printed circuit board 310. The conductive coupling may be achieved with any suitable connector that allows electrical signals to pass between the transmission line and the printed circuit board 310 to which the transmission line is conductively coupled. For example, an exposed second end of transmission line 314a may be conductively coupled to the printed circuit board 310 by a connector 324a in a multi-pin connector 320. An exposed second end of transmission line 314b may be conductively coupled to the printed circuit board 310 by a connector 324b in the multi-pin connector 320. An exposed second end of transmission line 314c may be conductively coupled to the printed circuit board 310 by a connector 324c in the multi-pin connector 320. An exposed second end of transmission line 314d may be conductively coupled to the printed circuit board 310 by a connector 324d in the multi-pin connector 320.

Although the first ends of transmission lines 314a-314d are illustrated as being coupled to the peripheral components 340 with individual connectors, such connections could alternatively be implemented using a multi-pin or multi-terminal connector depending on the size and placement of the peripheral components 340 in the chassis. Similarly, although the second ends of transmission lines 314a-314d are illustrated as being coupled to the printed circuit board 310 with a multi-pin (or multi-terminal) connector, such connections could alternatively be implemented using individual connectors (e.g., individual spring-loaded pins, individual spring terminals, etc.).

In this example, transmission line 314a can route speaker amplifier signals. Transmission line 314b can route specific exception rate (SAR) signals, transmission line 314c can route Hall sensor signals. Other transmission lines could route other sensor signals including, but not necessarily limited to accelerometer signals, gyro meter or gyroscope signals, and ambient light sensor (ALS) signals. Transmission line 314d can route microphone mute signals and/or privacy switch signals. The speed of the low-speed signals vary depending on the particular peripheral component that is transmitting or receiving the signals and depending on the particular communication protocol being used. Generally, low-speed signals or non-impedance control signals (e.g., speakers, power button, sensors, etc.) can include signals in the range of 1 bit per second (bps) to 1.5 megabits per second (Mbps) and signals in the range of 1 hertz (Hz) to 10 megahertz (MHz). The transmission lines 314a-314d over which low-speed signals travel may use communication protocols such as Inter-Integrated Circuit (I2C), Serial Peripheral Interface (SPI), Universal Asynchronous Receiver-Transmitter (UART), General Purpose Input/Output (GPIO) digital signal pins, System Management Bus (SMBus), Low Pin Count (LPC) Bus, and/or some versions of Universal Serial Bus (USB) (e.g., USB 1.1), for example.

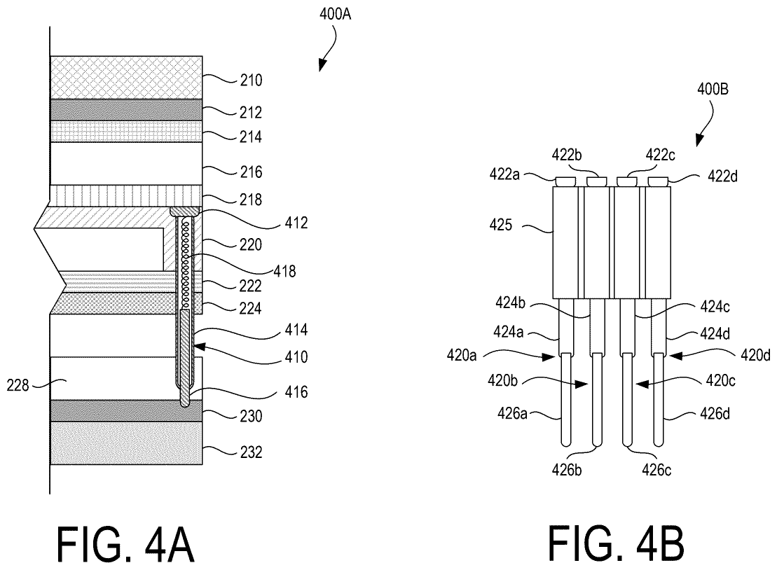

FIG. 4A is a cutaway view 400A of the cross-sectional side view of FIG. 2 illustrating an example connector that may be used in one or more embodiments. In FIG. 4A, a spring-loaded connector 410 (also referred to as a “pogo pin”) is used to conductively couple a transmission line in the heat and signal carrying member 230 to the printed circuit board 218. The spring-loaded connector 410 is illustrated in cross-section, with a non-sectioned interior coil spring 418. The spring-loaded connector 410 includes a base 412 that may be directly attached to a trace or any suitable conductive contact on the printed circuit board 218. The base 412 in FIG. 4A may be attached by soldering or pressing by a spring mechanism in some examples. In other example scenarios, the base may be attached by a docking mechanism if the pogo pin is contained in a housing.

The spring-loaded connector 410 further includes a barrel portion 414 with an interior cavity that holds the coil spring 418. A plunger portion 416 is provided at an end of the barrel. An inner end of the plunger portion 416 engages the coil spring 418 and an outer end of the plunger portion 416 extends past the end of the barrel portion 414. When inserted in the layered structure 200 of a chassis and connected to the printed circuit board 218 as shown in FIG. 4A, the plunger portion 416 compresses the coil spring 418 and the outer end of the plunger portion engages and presses against a transmission line in the heat and signal carrying member 230. Thus, the spring-loaded connector conductively couples the transmission line and the printed circuit board 218 and, when the computing system is in operation, enables electrical signals to pass between the transmission line and the printed circuit board 218 via the spring-loaded connector 410.

Other spring-loaded connectors may have plunger portions at each end of the barrel. In this scenario, one plunger portion (e.g., plunger portion 416) engages and presses against and end of the transmission line (or a conductive contact at the end of the transmission line) in the heat and signal carrying member 230 and the plunger portion at the opposite end of the barrel engages and presses against a trace or conductive contact on the printed circuit board 218.

For a peripheral component (e.g., similar to the peripheral components 340 of FIG. 3), a spring-loaded connector may have a base (e.g., base 412) that is connected to a wire, a conductive contact, or a printed circuit board of the peripheral component. In another example, the spring-loaded connector may have a plunger portion that is connected to a wire, a conductive contact, or a printed circuit board of the peripheral component. A plunger portion (e.g., similar to plunger portion 416) at the opposite end of the spring-loaded connector may be positioned to engage and press against an end of the transmission line (or a conductive contact at the end of the transmission line) of the heat and signal carrying member 230. Thus, a spring-loaded connector may conductively couple the transmission line and a peripheral component and, when the computing system is in operation, enable electrical signals to pass between the transmission line and the peripheral component via the spring-loaded connector.

FIG. 4B is a side view of an example multi-pin spring-loaded connector 400B that may be used in one or more embodiments. The multi-pin spring-loaded connector 400B may include multiple pins (e.g., two pins, three pins, four pins, or more). In this example, the multi-pin spring-loaded connector 400B includes four pins 420a, 420b, 420c, and 420d. The pins 420a, 420b, 420c, and 420d include respective bases 422a, 422b, 422c, and 422d, respective barrels 424a, 424b, 424c, and 424d, and respective plunger portions 426a, 426b, 426c, and 426d. The barrels 424a-424d may each have a cavity that holds a coil spring that is compressed to press and hold the plunger portion against an end of a transmission line or conductive contact at an end of the transmission line. The barrels 424a-424d are secured in a housing 425 such that the bases 422a-422d and the plunger portions 426a-426d are positioned in a side-by-side alignment. A pitch between each pair of plunger portions (e.g., plunger portions 426a and 426b, plunger portions 426b and 426c, and plunger portions 426c and 426d) may be in a range of 1.3 millimeters and 1.6 millimeters in at least some implementations. Thus, when using multi-pin spring-loaded connector 400B, the conductive contacts, traces, transmission lines, etc. to which the bases 422a-422d and the plunger portions 426a-426d may be correspondingly aligned in a side-by-side arrangement.

The above description of spring-loaded connectors 410 and multi-pin spring-loaded connectors 400B are intended to be for illustrative purposes and are not intended to be limiting. An individual or multi-pin spring-loaded connector may take numerous different forms and may be connected to any suitable combination of a printed circuit board, a transmission line, a peripheral component, and an electronic component to achieve a conductive coupling that enables low-speed signals to be transmitted across transmission lines on a heat and signal carrying member in a computing system. Embodiments disclosed herein are intended to include the numerous suitable types of connectors and connection techniques to enable transmissions of low-speed signals on transmission lines in a heat and signal carrying member (e.g. member 230) in a computing system.

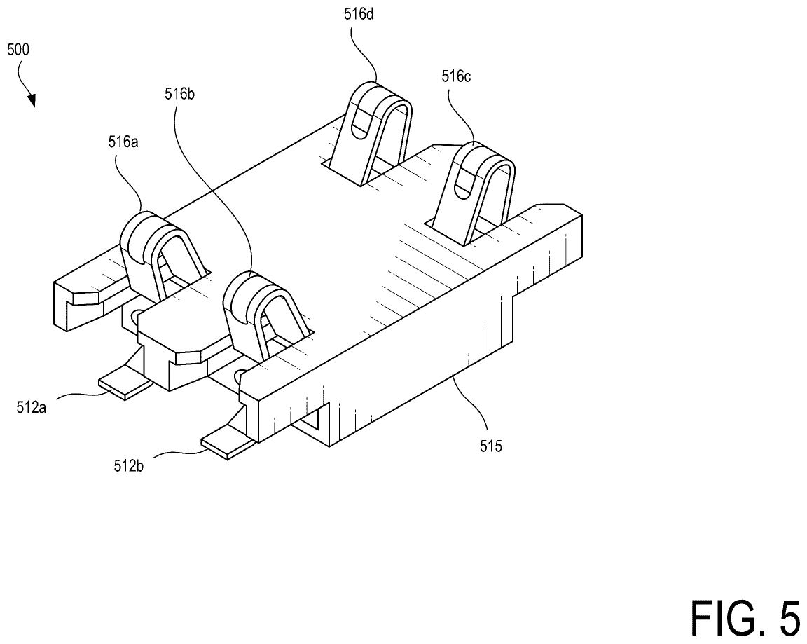

FIG. 5 is another example of a spring-loaded connector that may be used in one or more embodiments. FIG. 5 shows a multi-terminal spring-loaded terminal block 500 that may be used to conductively couple transmission lines in a heat and signal carrying member (e.g., heat and signal carrying member 110, 120, 230, 300) to a printed circuit board (e.g., printed circuit board 218) and to peripheral components (e.g., peripheral components 340). The spring-loaded terminal block 500 includes four terminals 516a, 516b, 516c, and 516d, secured in a block housing 515. A pitch between each pair of terminals (e.g., terminals 516a and 516b, and terminals 516c and 516d) may be in a range of 1.3 millimeters and 1.6 millimeters in at least some implementations. Each of the four terminals may include a spring-loaded conductive contact. For example, conductive contacts 512a and 512b correspond to terminals 516a and 516b, respectively. Conductive contacts that correspond to terminals 516c and 516d are not visible in the view of FIG. 5.

The spring mechanism may be used to press a terminal and/or conductive contact against a transmission line (e.g., in a heat and signal carrying member), against a line or trace (e.g., on a printed circuit board), or against another conductive contact (e.g., on a printed circuit board, a transmission line, or a peripheral component). Thus, the spring-loaded terminal block 500 may be used to conductively couple multiple peripheral components to multiple transmission lines and/or to conductively couple a printed circuit board to multiple transmission lines.

As embodiments involve routing low-speed signals, which do not require impedance control, an electrical connection using any of the connectors described herein (e.g., spring-loaded connectors 410, multi-pin spring-loaded connector 400B, multi-terminal spring-loaded terminal block 500) can be made using the force of the chassis (e.g., chassis 104, base panel 232), which typically weighs approximately 120 grams. Thus, at least one end of the connectors (e.g., plunger portions or base of pogo pins, terminals or conductive contacts of a spring terminal, etc.) may be pressed to engage and make an electrical connection with conductive contacts (e.g., on a printed circuit board, a transmission line, or a peripheral component) or with an end of a transmission line in a heat and signal carrying member by the weight of the chassis.

It should be noted that the particular conductive connectors shown and described herein are intended to be nonlimiting examples and any other spring-loaded conductive connector that can create an electrical connection between a transmission line and a conductive contact on PCB and/or between a transmission line and a conductive contact of peripheral component could also be used herein. In other examples, non spring-loaded connectors may be used to provide an electrical connection between a transmission line and a PCB by incorporating mechanical connections between the PCB and the heat and signal carrying member. Similarly non spring-loaded connectors may be used to provide an electrical connection between a transmission line and a peripheral component by incorporating mechanical connections between the peripheral component and the heat and signal carrying member.

FIGS. 6A-6E illustrate an example process for creating a heat and signal carrying member (e.g., similar to heat and signal carrying members 110, 120, 230, 300) with transmission lines (e.g., similar to transmission lines 114a, 114b, 124a, 124b, 314a, 314b, 314c, 314d) according to one or more embodiments.

The process begins in FIG. 6A with a base layer 610 comprising a material that has a high thermal conductivity. In some examples, the thermal conductivity of the base layer 610 may be in the range of 1000 to 1500 Watt per meter per Kelvin (W/mK). A base layer, however, can include any suitable material, such as a silver thermal compound, thermal grease, phase change materials, indium foils, or graphite sheets, for example. In some embodiments, the thickness dimension of the base layer 610 is 0.03 millimeters (mm). More generally, the base layer 610 may have a thickness dimension in the range of 0.075 mm to 0.25 mm. The width and length of the base layer 610 can be sized to provide heat dissipation of heat produced by electronic components in a chassis (e.g., electronic components 108 in second chassis 104) and to enable the formation of an electrically conductive path between one or more low-power peripheral components and a printed circuit board in the chassis.

In FIG. 6B, a lower layer 620a comprising a dielectric material is applied to an upper surface 612 of the base layer 610 such that the lower layer 620a is disposed on the base layer 610. In some embodiments, the thickness dimension of the lower layer 620a is 0.03 mm. More generally, the lower layer 620a may have a thickness dimension in the range of 0.01 mm to 0.1 mm.

In FIG. 6C, an interconnect layer 630 comprising an electrically conductive material such as a metal is formed on an upper surface 622 of lower layer 620a such that the interconnect layer 630 is disposed on the lower layer 620a. The interconnect layer 630 generally comprises a metal, such as copper (Cu). In some embodiments, the thickness dimension of the interconnect layer 630 is 0.03 mm. More generally, the interconnect layer 630 may have a thickness dimension in the range of 0.03 mm to 0.2 mm. In some embodiments, the interconnect layer 630 may include one or more of gold, tungsten, aluminum, titanium, tantalum, molybdenum, magnesium, and cobalt (W, Mo, Ti, Au, Mg, Ta, Co, Al). The interconnect layer 630 may be formed into one or more transmission lines (e.g., lines or traces) arranged to route electrical signals in a direction of a plane that is substantially parallel with a surface of the base layer 610. For example, the transmission lines may route electrical signals in a direction in and out of the page and/or in a direction across the page from the perspective of FIG. 6C. The transmission lines may be composed of the electrically conductive material (e.g., metal).

Any suitable techniques, such as printing or etching may be used to form the transmission lines. In one example, a metal layer may be applied to the upper surface 622 of the lower layer 620a and then etched to form the desired transmission lines. In another example, the transmission lines may be printed with the conductive material (e.g., copper, silver, carbon) directly onto the upper surface 622 of the lower layer 620a, without the need for etching.

In FIG. 6D, an upper layer 620b comprising a dielectric material is applied to the interconnect layer 630. The dielectric material may be applied to an upper surface 632 of the transmission lines in the interconnect layer 630 and fill in the open areas that define and separate transmission lines from each other. Thus, the dielectric material is interspersed with the electrically conductive material (e.g., the transmission lines) in the interconnect layer 630. In some embodiments, the thickness dimension of the upper layer 620b is 0.03 mm. More generally, the upper layer 620b may have a thickness dimension (measured from the upper surface 632 of the conductive layer 630 to an upper surface 624 of the upper layer 620b) in the range of 0.01 mm to 0.1 mm.

The lower layer 620a and upper layer 620b may be formed from materials that have the same composition or a different composition. For example, the lower layer 620a and upper layer 620b may be formed with a dielectric material having the same composition or different dielectric materials having different compositions. The lower layer 620a and upper layer 620b may include laminate, silicon oxide, silicon dioxide, silicon carbide, and/or a high-k dielectric material. The laminate dielectric materials may include polymide, fiberglass and epoxy (FR4), and composite epoxy (CEM-3). The high-k dielectric materials may include elements such as hafnium, silicon, oxygen, titanium, tantalum, lanthanum, aluminum, zirconium, barium, strontium, yttrium, lead, scandium, niobium, and zinc. Some specific examples of high-k materials that may be used include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

In FIG. 6E, an example portion 600 of the completed heat and signal carrying member is illustrated. In some embodiments, the thickness dimension of the completed heat and signal carrying member, as shown in the example portion 600 and measured from a bottom surface 614 of the base layer 610 to the upper surface 624 of the upper layer 620b, is 0.12 mm. More generally, the heat and signal carrying member may have a thickness dimension in the range of 0.1 mm to 0.3 mm. It should be noted that in at least some embodiments, a dielectric layer may also be applied to the bottom surface 614 of the base layer 610.

A suitable technique (e.g., etching) may be used to form contact areas 626 in the upper layer 620b to provide access to the transmission lines formed in the interconnect layer 630. In some techniques, a mask may be used to etch the appropriate areas of the upper layer 620b. The contact areas 626 can expose the transmission lines to enable conductive connectors (e.g., spring-loaded connectors 410, multi-pin spring-loaded connector 400B, multi-terminal spring-loaded terminal block 500) to engage the transmission lines and form electrical connections between the transmission lines in interconnect layer 630 and a printed circuit board and to form electrical connections between the transmission lines and peripheral components, in order to transmit low-power signals across the heat and signal carrying member.

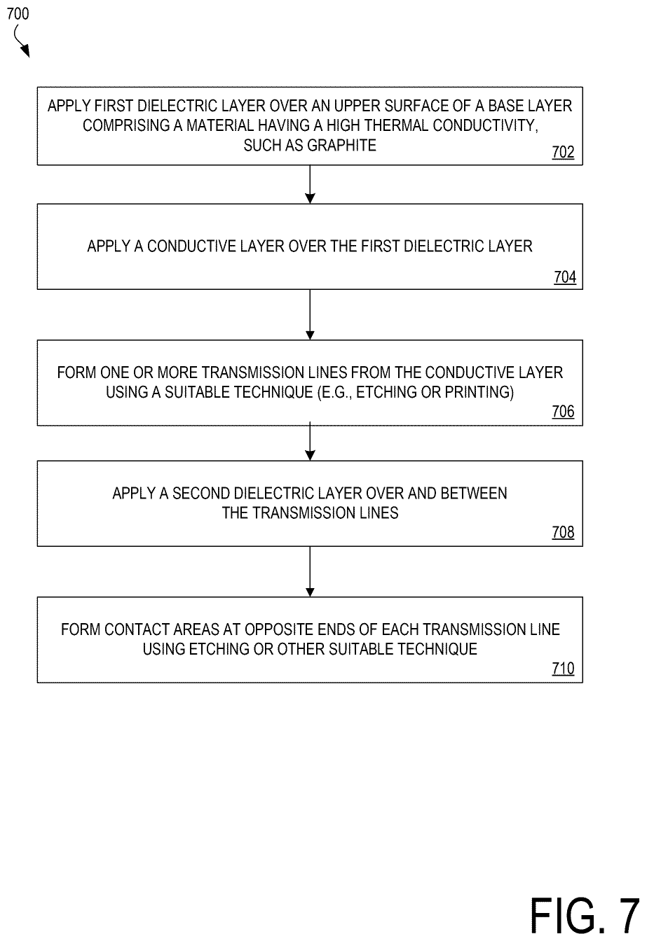

FIG. 7 is an example method of a process for creating a heat and signal carrying member having transmission lines according to one or more embodiments. At 702, a first dielectric layer is applied over an upper surface of a base layer comprising a material having a high thermal conductivity, such as graphite, for example.

An interconnect layer is formed on the dielectric layer. In one example as shown in FIG. 7, at 704, a conductive layer comprising metal is applied over the first dielectric layer. The conductive layer may be applied directly onto an upper surface of the first dielectric layer. At 706, one or more transmission lines are formed from the conductive layer. Any suitable technique such as etching may be used to form the transmission lines.

In another example process for forming the interconnect layer, transmission lines are formed on the first dielectric layer by printing the transmission lines directly on an upper surface of the dielectric layer.

At 708, a second dielectric layer is applied over and between the one or more transmission lines in the interconnect layer. The second dielectric layer may be applied directly onto the transmission lines and may fill in the open areas in the interconnect layer that define and separate the transmission lines. When etching is used to form transmission lines, these open areas are formed during the etching process to create the transmission lines. When printing is used to form transmission lines, these open areas are formed when the transmission lines are printed onto the first dielectric layer.

At 710, contact areas (e.g., openings, holes, cavities, etc.) are formed in the second dielectric layer above opposite ends of each of the transmission lines. Contact areas (e.g., contact areas 626 of FIG. 6E) can be created by etching away portions of the second dielectric layer to expose opposite ends of each of the transmission lines.

Once the heat and signal carrying member has been made, the method 700 can comprise one or more additional elements. For example, the method 700 can further comprise connecting one contact member (e.g., plunger portion, base, terminal, conductive contact) of a first conductive connector to a conductive contact on a printed circuit board of an electronic device, and further connecting another contact member of the first conductive connector to a transmission line at a first contact area in the second dielectric layer of the heat and signal carrying member. The method 700 can further comprise connecting one contact member (e.g., plunger, base, terminal, conductive contact) of a second conductive connector to a conductive contact of a peripheral component in the electronic device, and further connecting another contact member of the second conductive connector to the transmission line at a second contact area in the second dielectric layer of the heat and signal carrying member. The method of connecting the first and second conductive connectors may be repeated with additional conductive connectors for each of the transmission lines and corresponding peripheral components to form electrically conductive paths between the peripheral components and the printed circuit board using respective transmission lines in the heat and signal carrying member. The method 700 can further comprise affixing (e.g., gluing, fastening, or otherwise connecting) the heat and signal carrying member to the chassis (e.g., base panel 232). In one or more implementations, the base layer (e.g., base layer 610) of the heat and signal carrying member or a dielectric layer applied to the bottom surface of the base layer, if present, faces the chassis. For example, the base layer 610 (or dielectric layer on the bottom surface of the base layer) may be glued to the base panel (e.g., base panel 232).

The technologies described herein can be implemented in any of a variety of computing systems, including mobile computing systems (e.g., smartphones, handheld computers, tablet computers, laptop computers, portable gaming consoles, 2-in-1 convertible computers, portable all-in-one computers), non-mobile computing systems (e.g., desktop computers, servers, workstations, stationary gaming consoles, set-top boxes, smart televisions, rack-level computing solutions (e.g., blade, tray, or sled computing systems)), and embedded computing systems (e.g., computing systems that are part of a vehicle, smart home appliance, consumer electronics product or equipment, manufacturing equipment).

As used herein, the term “computing system” includes computing devices and includes systems comprising multiple discrete physical components. In some embodiments, the computing systems are located in a data center, such as an enterprise data center (e.g., a data center owned and operated by a company and typically located on company premises), managed services data center (e.g., a data center managed by a third party on behalf of a company), a colocated data center (e.g., a data center in which data center infrastructure is provided by the data center host and a company provides and manages their own data center components (servers, etc.)), cloud data center (e.g., a data center operated by a cloud services provider that hosts companies'applications and data), or an edge data center (e.g., a data center typically having a smaller footprint than other data center types, located close to the geographic area that it serves).

FIG. 8 is a block diagram of an example computing system in which technologies described herein may be implemented. For example, the computing system of FIG. 8 and variations thereof could be implemented in computing device 100 of FIGS. 1A and 1B. Generally, components shown in FIG. 8 can communicate with other shown components, although not all connections are shown, for ease of illustration. Multiprocessor system 800 is an interfaced system and includes a plurality of processors or cores including a first processor 870 and a second processor 880 coupled via an interface 850 such as a point-to-point (P-P) interconnect, a fabric, and/or bus. In some examples, the first processor 870 and second processor 880 are homogeneous. In some examples, first processor 870 and second processor 880 are heterogenous. Though the example system 800 is shown to have two processors, the system may have three or more processors or may be a single processor system. In some examples, the computing system is a system on a chip (SoC), such as SOC 220 of the layered structure 200 of FIG. 2.

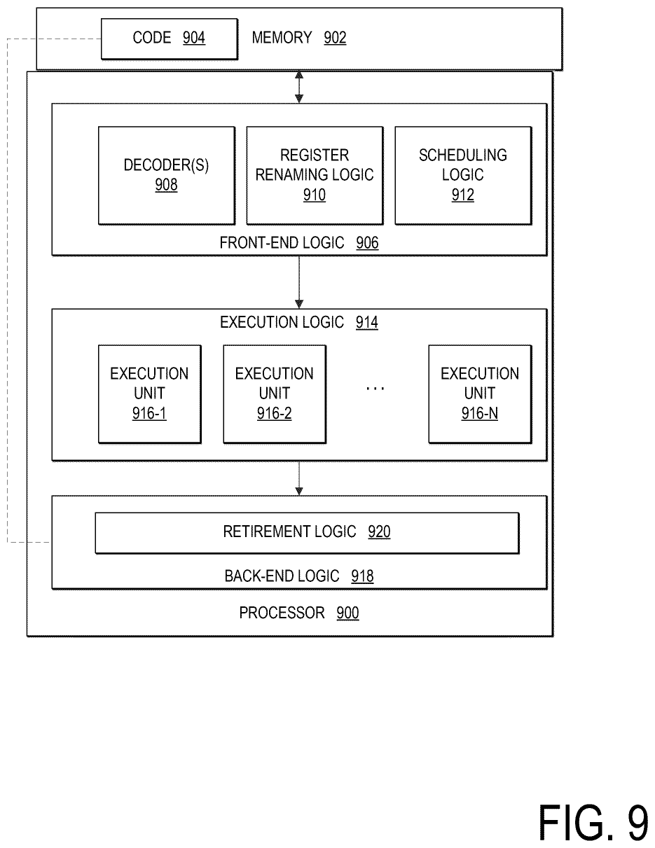

First processor 870 and second processor 880 comprise multiple processor cores. First processor 870 comprises processor cores 874 and second processor 880 comprises processor cores 884. Processor cores 874 and 884 can execute computer-executable instructions in a manner similar to that discussed below in connection with FIG. 9, or other manners.

Processors 870 and 880 may include single or multiple cores 874 and 884, respectively. Accordingly, processor 870 and 880 can be implemented as single core processors or multi-core processors. Processors 870 and 880 may each include a cache 871 and 881 used by their respective core or cores. A shared cache (not shown) may be included in either processor or outside of both processors, yet connected with the processors via P-P interconnect, such that either or both processors'local cache information may be stored in the shared cache if a processor is placed into a low power mode.

The cache 871 and 881 are cache memories that can store data (e.g., instructions) utilized by one or more components of first processor 870 and second processor 880, such as the processor cores 874 and 884. The cache 871 and 881 can be part of a memory hierarchy for the computing system 800. For example, the cache 871 can locally store data that is also stored in a first memory 832 to allow for faster access to the data by first processor 870, and the cache 881 can locally store data that is also stored in a second memory 834 to allow for faster access to the data by second processor 880.

In some embodiments, the cache 871 and 881 can comprise multiple cache memories that are a part of a memory hierarchy. The cache memories in the memory hierarchy can be at different cache memory levels, such as level 1 (L1), level 2 (L2), level 3 (L3), level 4 (L4), or other cache memory levels. In some embodiments, one or more levels of cache memory (e.g., L2, L3, L4) can be shared among multiple cores in a processor or among multiple processors in an integrated circuit component. In some embodiments, the last level of cache memory in an integrated circuit component can be referred to as a last-level cache (LLC). One or more of the higher levels of cache levels (the smaller and faster cache memories) in the memory hierarchy can be located on the same integrated circuit die as a processor core and one or more of the lower cache levels (the larger and slower caches) can be located on one or more integrated circuit dies that are physically separate from the processor core integrated circuit dies.

Although the computing system 800 is shown with two processors, the computing system 800 can comprise any number of processors. Further, a processor can comprise any number of processor cores. A processor can take various forms such as a central processing unit (CPU), graphics processing unit (GPU), general-purpose GPU (GPGPU), accelerated processing unit (APU), field-programmable gate array (FPGA), neural network processing unit (NPU), data processor unit (DPU), accelerator (e.g., graphics accelerator, digital signal processor (DSP), compression accelerator, artificial intelligence (AI) accelerator), controller, or other type of processing unit. As such, the processor can be referred to as an XPU (or xPU). Further, a processor can comprise one or more of these various types of processing units. In some embodiments, the computing system comprises one processor with multiple cores, and in other embodiments, the computing system comprises a single processor with a single core. As used herein, the terms “processor” and “processing unit” can refer to any processor unit, processor core, component, module, engine, circuitry, or any other processing element described or referenced herein.

In some embodiments, the computing system 800 can comprise one or more processors that are heterogeneous or asymmetric to another processor in the computing system. There can be a variety of differences between the processing units in a system in terms of a spectrum of metrics of merit including architectural, microarchitectural, thermal, power consumption characteristics, and the like. These differences can effectively manifest themselves as asymmetry and heterogeneity among the processors in a system.

First processor 870 and second processor 880 can be located in a single integrated circuit component (such as a multi-chip package (MCP) or multi-chip module (MCM)) or they can be located in separate integrated circuit components. An integrated circuit component comprising one or more processors can comprise additional components, such as embedded DRAM, stacked high bandwidth memory (HBM), shared cache memories (e.g., L3, L4, LLC), input/output (I/O) controllers, or memory controllers. Any of the additional components can be located on the same integrated circuit die as a processor, or on one or more integrated circuit dies separate from any integrated circuit die containing a processor. In some embodiments, these separate integrated circuit dies can be referred to as “chiplets”. In some embodiments, where there is heterogeneity or asymmetry among processors in a computing system, the heterogeneity or asymmetric can be among processors located in the same integrated circuit component. In embodiments where an integrated circuit component comprises multiple integrated circuit dies, interconnections between dies can be provided by a package substrate, one or more silicon interposers, one or more silicon bridges embedded in a package substrate (such as Intel® embedded multi-die interconnect bridges (EMIBs)), or combinations thereof.

First processor 870 further comprises first integrated memory controller logic (first IMC 872) and second processor 880 further comprises second memory controller logic (second IMC 882). As shown in FIG. 8, a first memory 832 coupled to first processor 870 is controlled by the first IMC 872 and a second memory 834 coupled to second processor 880 is controlled by the second IMC 882. The first memory 832 and the second memory 834 can comprise various types of volatile memory (e.g., dynamic random-access memory (DRAM), static random-access memory (SRAM)) and/or non-volatile memory (e.g., flash memory, chalcogenide-based phase-change non-volatile memories). The first memory 832 and the second memory 834 can comprise one or more layers of a memory hierarchy of the computing system. While first IMC 872 and second IMC 882 are illustrated as being integrated into first processor 870 and second processor 880, in alternative embodiments, memory controller logic can be external to a processor.

First processor 870 also includes interface circuits 876 and 878; similarly, second processor 880 includes interface circuits 886 and 888. Processors 870, 880 may exchange information via the interface 850 using interface circuits 878, 888.

Processors 870, 880 may each exchange information with a network interface (NW I/F) 890 via individual interfaces 852, 854, such as a point-to-point (P-P) interconnect, a fabric, and/or bus, using interface circuits 876, 894, 886, 898. The network interface 890 (e.g., one or more of an interconnect, bus, and/or fabric, and in some examples is a chipset) may optionally exchange information with a coprocessor 838 via an interface circuit 892. In some examples, the coprocessor 838 is a special-purpose processor, such as, for example, a high-throughput processor, a network or communication processor, compression engine, graphics processor, general purpose graphics processing unit (GPGPU), neural-network processing unit (NPU), embedded processor, or the like. Network interface 890 may also provide information to a display 833 using an interface circuitry 893, for display to a human user.

Network interface 890 may be coupled to a first interface 810 via interface circuit 896. In some examples, first interface 810 may be an interface such as a Peripheral Component Interconnect (PCI) interconnect, a PCI Express interconnect or another I/O interconnect. In some examples, first interface 810 is coupled to a power control unit (PCU) 817, which may include circuitry, software, and/or firmware to perform power management operations with regard to the processors 870, 880 and/or co-processor 838. PCU 817 provides control information to a voltage regulator (not shown) to cause the voltage regulator to generate the appropriate regulated voltage. PCU 817 also provides control information to control the operating voltage generated. In various examples, PCU 817 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 817 is illustrated as being present as logic separate from the processor 870 and/or processor 880. In other cases, PCU 817 may execute on a given one or more of cores (not shown) of processor 870 or 880. In some cases, PCU 817 may be implemented as a microcontroller (dedicated or general-purpose) or other control logic configured to execute its own dedicated power management code, sometimes referred to as P-code. In yet other examples, power management operations to be performed by PCU 817 may be implemented externally to a processor, such as by way of a separate power management integrated circuit (PMIC) or another component external to the processor. In yet other examples, power management operations to be performed by PCU 817 may be implemented within BIOS or other system software.

Various I/O devices 814 may be coupled to first interface 810, along with a bus bridge 818 which couples first interface 810 to a second interface 820. In some examples, one or more additional processor(s) 815, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 810. In some examples, second interface 820 may be a low pin count (LPC) interface. Various devices may be coupled to second interface 820 including, for example, a user interface 822 (such as a keyboard, mouse, touchscreen, or other input devices), communication devices 826 (such as modems, network interface devices, or other types of communication devices that may communicate through a computer network and provide for communication between the computing system 800 and one or more wired and/or wireless networks), and storage circuitry 828. Storage circuitry 828 may be one or more non-transitory machine-readable storage media as described below, such as a disk drive or other mass storage device which may include instructions/code and data 830. Further, an audio I/O 824 may be coupled to second interface 820. Note that other architectures than the point-to-point architecture described above are possible. For example, instead of the point-to-point architecture, a system such as multiprocessor system 800 may implement a multi-drop interface or other such architecture. Any of the various I/O devices that use low-speed signals may be conductively coupled to a transmission line formed in a heat and signal carrying member (e.g., heat and signal carrying member 110, 120, 230, 300) to provide an electrical pathway to electronic components on the motherboard or other PCB according to one or more embodiments.

In embodiments where the one or more communication devices 826 support wireless communication, the one or more communication devices 826 can comprise wireless communication components coupled to one or more antennas to support communication between the computing system 800 and external devices via one or more wired or wireless networks 840. The wireless communication components can support various wireless communication protocols and technologies such as Near Field Communication (NFC), IEEE 1002.11 (Wi-Fi) variants, WiMax, Bluetooth, Zigbee, 4G Long Term Evolution (LTE), Code Division Multiplexing Access (CDMA), Universal Mobile Telecommunication System (UMTS) and Global System for Mobile Telecommunication (GSM), and 5G broadband cellular technologies. In addition, the wireless modems can support communication with one or more cellular networks for data and voice communications within a single cellular network, between cellular networks, or between the computing system and a public switched telephone network (PSTN).

The computing system 800 can comprise removable memory such as flash memory cards (e.g., SD (Secure Digital) cards), memory sticks, Subscriber Identity Module (SIM) cards). The memory in computing system 800 (including cache 871 and 881, first memory 832, second memory 834, and storage circuitry 828) can store data and/or computer-executable instructions for executing an operating system 804 and application programs 806. Example data includes web pages, text messages, images, sound files, and video data to be sent to and/or received from one or more network servers or other devices by the computing system 800 via one or more wired or wireless networks, or for use by the computing system 800. The computing system 800 can also have access to external memory or storage (not shown) such as external hard drives or cloud-based storage.

The operating system 804 can control the allocation and usage of the components illustrated in FIG. 8 and support the application programs 806. The application programs 806 can include common computing system applications (e.g., email applications, calendars, contact managers, web browsers, messaging applications) as well as other computing applications.

The computing system 800 can support various additional input devices, such as a touchscreen, microphone, monoscopic camera, stereoscopic camera, trackball, touchpad, trackpad, proximity sensor, light sensor, electrocardiogram (ECG) sensor, PPG (photoplethysmogram) sensor, galvanic skin response sensor, and one or more output devices, such as one or more speakers or displays. Other possible input and output devices include piezoelectric and other haptic I/O devices. Any of the input or output devices can be internal to, external to, or removably attachable with the computing system 800. External input and output devices can communicate with the computing system 800 via wired or wireless connections. Any of the additional input devices that use low-speed signals may be conductively coupled to a transmission line formed in a heat and signal carrying member (e.g., heat and signal carrying member 110, 120, 230, 300) to provide an electrical pathway to electronic components on the motherboard or other PCB according to one or more embodiments.

The computing system 800 can further include at least one input/output port comprising physical connectors (e.g., USB, FireWire, Ethernet, RS-232), a power supply (e.g., battery), a global satellite navigation system (GNSS) receiver (e.g., GPS receiver); a gyroscope; an accelerometer; and/or a compass. A GNSS receiver can be coupled to a GNSS antenna. The computing system 800 can further comprise one or more additional antennas coupled to one or more additional receivers, transmitters, and/or transceivers to enable additional functions.

In addition to those already discussed, integrated circuit components, integrated circuit constituent components, and other components in the computing system 800 can communicate via interconnect technologies such as Intel® QuickPath Interconnect (QPI), Intel® Ultra Path Interconnect (UPI), Computer Express Link (CXL), cache coherent interconnect for accelerators (CCIX®), serializer/deserializer (SERDES), Nvidia® NVLink, ARM Infinity Link, Gen-Z, or Open Coherent Accelerator Processor Interface (OpenCAPI). Other interconnect technologies may be used and a computing system 800 may utilize more or more interconnect technologies.

It is to be understood that FIG. 8 illustrates only one example computing system architecture. Computing systems based on alternative architectures can be used to implement technologies described herein. For example, instead of first processor 870, second processor 880, and a coprocessor 838 (e.g., graphics engine) being located on discrete integrated circuit dies, a computing system can comprise an SoC (system-on-a-chip) integrated circuit die on which multiple processors, a graphics engine, and additional components are incorporated. Further, a computing system can connect its constituent component via bus or point-to-point configurations different from that shown in FIG. 8. Moreover, the illustrated components in FIG. 8 are not required or all-inclusive, as shown components can be removed and other components added in alternative embodiments.

FIG. 9 is a block diagram of an example processor to execute computer-executable instructions and which may be implemented in an electronic device (e.g., computing device 100) according to one or more embodiments described herein. The processor 900 can be a single-threaded core or a multithreaded core in that it may include more than one hardware thread context (or “logical processor”) per processor.

FIG. 9 also illustrates a memory 902 coupled to the processor 900. The memory 902 can be any memory described herein or any other memory known to those of skill in the art. The memory 902 can store data and code 904. The code 904 (e.g., computer-executable instructions) may be executable by processor 900.

The processor comprises front-end logic 906 that receives instructions from memory 902. An instruction can be processed by one or more decoders 908. The one or more decoders 908 can generate as its output a micro-operation such as a fixed width micro-operation in a predefined format, or generate other instructions, microinstructions, or control signals, which reflect the original code instruction. The front-end logic 906 further comprises register renaming logic 910 and scheduling logic 912, which generally allocate resources and queues operations corresponding to converting an instruction for execution.

The processor 900 further comprises execution logic 914, which comprises one or more execution units (EUs) (execution unit 916-1, 916-2 through execution unit 916-N). Some processor embodiments can include a number of execution units dedicated to specific functions or sets of functions. Other embodiments can include only one execution unit or one execution unit that can perform a particular function. The execution logic 914 performs the operations specified by code instructions. After completion of execution of the operations specified by the code instructions, back-end logic 918 retires instructions using retirement logic 920. In some embodiments, the processor 900 allows out of order execution but requires in-order retirement of instructions. Retirement logic 918 can take a variety of forms as known to those of skill in the art (e.g., re-order buffers or the like).

The processor 900 is transformed during execution of instructions, at least in terms of the output generated by the one or more decoders 908, hardware registers and tables utilized by the register renaming logic 910, and any registers (not shown) modified by the execution logic 914.

Any of the disclosed methods (or a portion thereof) can be implemented as computer-executable instructions or a computer program product. Such instructions can cause a computing system or one or more processors capable of executing computer-executable instructions to perform any of the disclosed methods. As used herein, the term “computer” refers to any computing system, device, or machine described or mentioned herein as well as any other computing system, device, or machine capable of executing instructions. Thus, the term “computer-executable instruction” refers to instructions that can be executed by any computing system, device, or machine described or mentioned herein as well as any other computing system, device, or machine capable of executing instructions.

The computer-executable instructions or computer program products as well as any data created and/or used during implementation of the disclosed technologies can be stored on one or more tangible or non-transitory computer-readable storage media, such as volatile memory (e.g., DRAM, SRAM), non-volatile memory (e.g., flash memory, chalcogenide-based phase-change non-volatile memory) optical media discs (e.g., DVDs, CDs), and magnetic storage (e.g., magnetic tape storage, hard disk drives). Computer-readable storage media can be contained in computer-readable storage devices such as solid-state drives, USB flash drives, and memory modules. Alternatively, any of the methods disclosed herein (or a portion) thereof may be performed by hardware components comprising non-programmable circuitry. In some embodiments, any of the methods herein can be performed by a combination of non-programmable hardware components and one or more processing units executing computer-executable instructions stored on computer-readable storage media.

By way of example, for some peripheral components or I/O devices, computer-executable instructions executed by a processor on a PCB can cause low-speed signals to be transmitted to a peripheral component (e.g., peripheral components 340 or I/O devices disclosed herein) or to be received from a peripheral component via a transmission line in a heat and signal carrying member (e.g., 110, 120, 230, 300), where the transmission line is conductively coupled to both the processor (via the PCB to which the processor is attached) and to the peripheral component. In another example, a hardware component on a PCB may cause low-speed signals to be sent to a peripheral component (e.g., peripheral components 340 or I/O devices disclosed herein) or to be received from a peripheral component via a transmission line in a heat and signal carrying member (e.g., 110, 120, 230, 300), wherein the transmission line is conductively coupled to both the hardware component (via the PCB to which the hardware component is attached) and to the peripheral component.

Computer-executable instructions can be part of, for example, an operating system of the computing system, an application stored locally to the computing system, or a remote application accessible to the computing system (e.g., via a web browser). Any of the methods described herein can be performed by computer-executable instructions performed by a single computing system or by one or more networked computing systems operating in a network environment. Computer-executable instructions and updates to the computer-executable instructions can be downloaded to a computing system from a remote server.

Further, it is to be understood that implementation of the disclosed technologies is not limited to any specific computer language or program. For instance, the disclosed technologies can be implemented by software written in C++, C#, Java, Perl, Python, JavaScript, Adobe Flash, C#, assembly language, or any other programming language. Likewise, the disclosed technologies are not limited to any particular computer system or type of hardware.

Furthermore, any of the software-based embodiments (comprising, for example, computer-executable instructions for causing a computer to perform any of the disclosed methods) can be uploaded, downloaded, or remotely accessed through a suitable communication means. Such suitable communication means include, for example, the Internet, the World Wide Web, an intranet, cable (including fiber optic cable), magnetic communications, electromagnetic communications (including RF, microwave, ultrasonic, and infrared communications), electronic communications, or other such communication means.

In the above description, specific details are set forth, but embodiments of the technologies described herein may be practiced without these specific details. Well-known components, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or in any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. As used herein, the term “adjacent” refers to layers or components that are arranged next to each other (e.g., side-by-side, top and bottom).

Certain terminology may also be used herein for reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation and/or location of layers, components, portions of components, etc., within a consistent but arbitrary frame of reference, which is made clear by reference to the text and the associated Figures describing the layers, component, portions of components, etc. under discussion. Such terminology may include the words specifically mentioned above, derivatives thereof, and words of similar import.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processors mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor (e.g., system-on-a-chip (SoC), processor core, graphics processor unit (GPU), accelerator, chipset processor), I/O controller, memory, or network interface controller.

As used herein, the term “electronic component” can refer to an active electronic component (e.g., processor, processing unit, microprocessor memory, storage device, battery, etc.) attached to a printed circuit board, or a battery or a peripheral component that is not attached to a PCB, or that is attached to a PCB other than the PCB or motherboard where the other electronic components are attached.

As used herein, the terms “operating”, “executing”, or “running” as they pertain to software or firmware in relation to a system, device, platform, or resource are used interchangeably and can refer to software or firmware stored in one or more computer-readable storage media accessible by the system, device, platform or resource, even though the software or firmware instructions are not actively being executed by the system, device, platform, or resource.

As used herein, the phrase “conductively coupled” refers to the presence of one or more electrically conductive paths between components that are recited as being electrically coupled. Furthermore, electrically conductive paths correspond to electrically conductive transmission lines and traces that are to conduct electrical signals when the computing device 100 of FIGS. 1A and 1B is in operation. For example, with reference to FIG. 3, the printed circuit board 310 is conductively coupled to the peripheral components 340 due to the presence of electrically conductive paths created by transmission lines 314a-314d through the heat and signal carrying member 300, connectors 324a-324d connecting the printed circuit board 310 to first ends of the transmission lines 314a-314d, and connectors 334a-334d connecting the peripheral components 340 to opposite ends of the transmission lines 314a-314d. In addition, for each peripheral component, the electrically conductive path may extend to an appropriate electronic component (e.g., processor, microprocessor, controller, etc.) on the printed circuit board 310 with which that peripheral component communicates and/or interacts.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

The following examples pertain to some embodiments of technologies disclosed herein. The system, apparatus, method, computing device embodiments can include one or a combination of the following examples.

Example C1 provides a computing device that includes: a printed circuit board, a member, and a peripheral component, and the member includes a first layer, a second layer, and a third layer, and the first layer includes a thermally conductive material, and the second layer includes a dielectric material, and the third layer includes a first transmission line, and the first peripheral component is conductively coupled to the printed circuit board by the first transmission line of the member.

Example C2 comprises the subject matter of Example C1, and the thermally conductive material includes graphite.

Example C3 comprises the subject matter of any one of Examples C1-C2, and the third layer includes metal interspersed with a second dielectric material.

Example C4 comprises the subject matter of Example C3, and the first transmission line is composed of the metal in the third layer.

Example C5 comprises the subject matter of any one of Examples C1-C4, and the first peripheral component is to send first signals to the printed circuit board over the first transmission line according to a first communication protocol.

Example C6 comprises the subject matter of Example C5, and the first communication protocol is one of a serial peripheral interface (SPI), a general peripheral input/output (GPIO), an inter-integrated circuit (I2C), or a universal asynchronous receiver-transmitter (UART).

Example C7 comprises the subject matter of any one of Examples C1-C6, and the third layer of the member further includes at least a second transmission line.

Example C8 comprises the subject matter of Example C7, and a second peripheral component is to send second signals to the printed circuit board over the second transmission line according to a second communication protocol.

Example C9 comprises the subject matter of any one of Examples C1-C8, and further comprising a third peripheral component conductively coupled to the printed circuit board by the third transmission line.

Example C10 comprises the subject matter of any one of Examples C1-C9, and further comprising a first connector connecting the first peripheral component to the first transmission line, and a second connector connecting the printed circuit board to the first transmission line.

Example A1 provides an apparatus including a graphite sheet with an upper surface, a first layer including a first dielectric material disposed on the upper surface of the graphite sheet, a second layer including an electrically conductive material disposed on the first layer and comprising a first transmission line, and a third layer including a second dielectric material disposed on the second layer, and the third layer defines a first opening that exposes a first end of the first transmission line and a second opening that exposes a second end of the first transmission line.

Example A2 comprises the subject matter of Example A1, and the first transmission line is to transmit first signals between a first peripheral component and a printed circuit board according to a first communication protocol.

Example A3 comprises the subject matter of Example A2, and a first connector is to conductively couple the first end of the first transmission line to the first peripheral component, and a second connector is to conductively couple the second end of the first transmission line to the printed circuit board.

Example A4 comprises the subject matter of any one of Examples A2-A3, and the first communication protocol is one of a serial peripheral interface (SPI), a general peripheral input/output (GPIO), an inter-integrated circuit (I2C), or a universal asynchronous receiver-transmitter (UART).

Example A5 comprises the subject matter of any one of Examples A2-A4, and the second layer comprises at least a second transmission line to transmit second signals between a second peripheral component and the printed circuit board according to a second communication protocol.

Example A6 comprises the subject matter of Example A5, and the second communication protocol is one of a serial peripheral interface (SPI), a general peripheral input/output (GPIO), an inter-integrated circuit (I2C), or a universal asynchronous receiver-transmitter (UART).

Example A7 comprises the subject matter of any one of Examples A1-A6, and a first composition of the first dielectric material is equivalent to or different than a second composition of the second dielectric material.

Example A8 comprises the subject matter of any one of Examples A1-A7, and the first layer, the second layer, and the third layer include a laminate material.

Example A9 comprises the subject matter of any one of Examples A1-A8, and the electrically conductive material of the second layer includes copper.

Example A10 comprises the subject matter of any one of Examples A1-A9, and the apparatus has a thickness dimension in a range of 0.1 millimeters to 0.3 millimeters as measured from a top surface of the third layer to a bottom surface of the graphite sheet.

Example S1 provides a system that includes a first chassis, a member at least partially disposed in the first chassis, and a processor disposed in the first chassis, and the member comprises a first layer including a thermally conductive material, a second layer disposed above the first layer and including a dielectric material, and a third layer disposed above the second layer and including a plurality of transmission lines, and the third layer includes an electrically conductive material, and the processor is to execute one or more instructions to cause the processor to receive a first signal sent from a first peripheral component over a first transmission line of the plurality of transmission lines according to a first communication protocol.

Example S2 comprises the subject matter of Example S1, and the processor is attached to a printed circuit board positioned in the first chassis such that the processor is disposed between the printed circuit board and the member.

Example S3 comprises the subject matter of any one of Examples S1-S2, and the member is positioned in the first chassis such that the second layer and the third layer are between the first layer and a printed circuit board.

Example S4 comprises the subject matter of any one of Examples S1-S3, and further comprising first means for conductively coupling the first transmission line to the first peripheral component, and second means for conductively coupling the first transmission line to a printed circuit board in the first chassis.

Example S5 comprises the subject matter of any one of Examples S1-S4, and the member extends from the first chassis to a second chassis mechanically coupled to the first chassis.

Example S6 comprises the subject matter of any one of Examples S1-S5, and the first communication protocol is one of a serial peripheral interface (SPI), a general peripheral input/output (GPIO), an inter-integrated circuit (I2C), or a universal asynchronous receiver-transmitter (UART).

Example S7 comprises the subject matter of any one of Examples S1-S6, and the thermally conductive material includes graphite.

Example S8 comprises the subject matter of any one of Examples S1-S7, and the processor is to execute other instructions to cause the processor to send a second signal sent to a second peripheral component over a second transmission line of the plurality of transmission lines according to a second communication protocol.

Example S9 comprises the subject matter of Example S8, and the second communication protocol is one of a serial peripheral interface (SPI), a general peripheral input/output (GPIO), an inter-integrated circuit (I2C), or a universal asynchronous receiver-transmitter (UART).

Example S10 comprises the subject matter of any one of Examples S1-S9, and the member includes a fourth layer disposed above the third layer and including the dielectric material, and the third layer further includes the dielectric material interspersed with the plurality of transmission lines.

Example M1 provides a method including applying a first layer directly on top of an upper surface of a base layer, and the first layer includes a first dielectric material, and the base layer comprises a thermally conductive material, forming a second layer on the first layer, and the second layer includes a first transmission line comprising an electrically conductive material, applying a third layer on the first second layer, and the third layer includes a second dielectric material, and forming contact areas in the third layer to expose a first end and a second end of the first transmission line.

Example M2 comprises the subject matter of Example M1, and the thermally conductive material includes graphite.

Example M3 comprises the subject matter of any one of Examples M1-M2, and the electrically conductive material includes copper.

Example M4 comprises the subject matter of any one of Examples M1-M3, and forming the second layer includes printing the first transmission line on a top surface of the second layer.

Example M5 comprises the subject matter of any one of Examples M1-M3, and forming the second layer includes applying the electrically conductive material on a top surface of the first layer, and removing one or more portions of the electrically conductive material on the top surface of the first layer to form the first transmission line from a remaining portion of the electrically conductive material.

Example M6 comprises the subject matter of any one of Examples M1-M5, and further comprising creating an electrically conductive path between a peripheral component and a printed circuit board via the first transmission line.

Example M7 comprises the subject matter of Example M6, and forming the electrically conductive path includes connecting a first connector to a first end of the first transmission line, connecting the first connector to a printed circuit board, connecting a second connector to a second end of the first transmission line, and connecting the second connector to the peripheral component.

Example M8 comprises the subject matter of any one of Examples M6-M7, and further comprising transmitting a first signal along the electrically conductive path between the printed circuit board and the peripheral component according to a first communication protocol.

Example M9 comprises the subject matter of Example M8, and the first communication protocol is one of a serial peripheral interface (SPI), a general peripheral input/output (GPIO), an inter-integrated circuit (I2C), or a universal asynchronous receiver-transmitter (UART).

Example M10 comprises the subject matter of any one of Examples M1-M9, and the second layer further includes a second transmission line comprising the electrically conductive material.

1. A computing device comprising:
a printed circuit board;
a member including a first layer, a second layer, and a third layer, wherein the first layer includes a thermally conductive material, the second layer includes a dielectric material, and the third layer includes a first transmission line; and
a first peripheral component conductively coupled to the printed circuit board by the first transmission line of the member.

2. The computing device of claim 1, wherein the thermally conductive material includes graphite.

3. The computing device of claim 1, wherein the third layer includes metal interspersed with a second dielectric material.

4. The computing device of claim 3, wherein the first transmission line is composed of the metal in the third layer.

5. The computing device of claim 1, wherein the first peripheral component is to send first signals to the printed circuit board over the first transmission line according to a first communication protocol.

6. The computing device of claim 5, wherein the first communication protocol is one of a serial peripheral interface (SPI), a general peripheral input/output (GPIO), an inter-integrated circuit (I2C), or a universal asynchronous receiver-transmitter (UART).

7. The computing device of claim 1, wherein the third layer of the member further includes at least a second transmission line.

8. The computing device of claim 7, further comprising:
a second peripheral component conductively coupled to the printed circuit board by the second transmission line.

9. The computing device of claim 8, wherein a second peripheral component is to send second signals to the printed circuit board over the second transmission line according to a second communication protocol.

10. The computing device of claim 1, further comprising:
a first connector connecting the first peripheral component to the first transmission line; and
a second connector connecting the printed circuit board to the first transmission line.

11. An apparatus comprising:
a graphite sheet with an upper surface;
a first layer including a first dielectric material disposed on the upper surface of the graphite sheet;
a second layer including a conductive material disposed on the first layer, wherein the second layer comprises a first transmission line; and
a third layer including a second dielectric material disposed on the second layer, wherein the third layer defines a first opening that exposes a first end of the first transmission line and a second opening that exposes a second end of the first transmission line.

12. The apparatus of claim 11, wherein, when a first connector is to conductively couple the first end of the first transmission line to a first peripheral component, and wherein a second connector is to conductively couple the second end of the first transmission line to a printed circuit board.

13. The apparatus of claim 12, wherein the first transmission line is to transmit first signals between the first peripheral component and the printed circuit board according to a first communication protocol.

14. The apparatus of claim 13, wherein the first communication protocol is one of a serial peripheral interface (SPI), a general peripheral input/output (GPIO), an inter-integrated circuit (I2C), or a universal asynchronous receiver-transmitter (UART).

15. The apparatus of claim 12, wherein the second layer comprises at least a second transmission line to transmit second signals between a second peripheral component and the printed circuit board according to a second communication protocol.

16. The apparatus of claim 11, wherein a first composition of the first dielectric material is equivalent to or different than a second composition of the second dielectric material.

17. A system comprising:
a first chassis;
a member at least partially disposed in the first chassis, wherein the member comprises a first layer including a thermally conductive material, a second layer disposed above the first layer and including a dielectric material, and a third layer disposed above the second layer and including a plurality of transmission lines, wherein the third layer includes an electrically conductive material; and
a processor disposed in the first chassis, wherein the processor is to execute one or more instructions to cause the processor to:
receive a first signal sent from a peripheral component over a first transmission line of the plurality of transmission lines according to a first communication protocol.

18. The system of claim 17, wherein the processor is attached to a printed circuit board positioned in the first chassis such that the processor is disposed between the printed circuit board and the member.

19. The system of claim 17, further comprising:
first means for conductively coupling the first transmission line to the peripheral component; and
second means for conductively coupling the first transmission line to a printed circuit board in the first chassis.

20. The system of claim 17, wherein the member extends from the first chassis to a second chassis mechanically coupled to the first chassis.
